(19) United States
(12) Patent Application Publication
(10) Pub. No.: US 2026/0040732 A1
(43) Pub. Date: Feb. 5, 2026

(54) OPTOELECTRONIC SEMICONDUCTOR COMPONENT, AND METHOD FOR PRODUCING AT LEAST ONE OPTOELECTRONIC SEMICONDUCTOR COMPONENT

(71) Applicant: ams-OSRAM International GmbH, Regensburg (DE)

(72) Inventor: Wolfgang SCHMID, Kelheim (DE)

(21) Appl. No.: 19/099,196

(22) PCT Filed: Jul. 20, 2023
(86) PCT No.: PCT/EP2023/070105

§ 371 Date: Jan. 28, 2025

(30) Foreign Application Priority Data
Jul. 29, 2022 (DE) 10 2022 119 108.7

(51) Int. Cl. H10H 20/831; H10H 20/01; H10H 20/812; H10H 20/819; H10H 20/824

(52) U.S. Cl. CPC H10H 20/8312; H10H 20/013; H10H 20/017; H10H 20/032; H10H 20/812; H10H 20/819; H10H 20/8242

(57) ABSTRACT

An optoelectronic semiconductor component includes a semiconductor layer stack including a first semiconductor region, a second semiconductor region, and an active zone arranged between the first and second semiconductor regions. The second semiconductor region includes a first semiconductor layer and a second semiconductor layer. The second semiconductor layer is arranged on a side of the first semiconductor layer facing away from the active zone. At least one depression extends from a first main surface of the semiconductor layer stack through the first semiconductor region and the active zone and ends at the second semiconductor layer. The first semiconductor layer includes a first compound semiconductor material and the second semiconductor layer includes a second compound semiconductor material. The first compound semiconductor material has a higher aluminum content than the second compound semiconductor material.

An optoelectronic semiconductor component and a method for producing at least one optoelectronic semiconductor component are specified. For example, the optoelectronic semiconductor component is an InGaAlP-based semiconductor component. The optoelectronic semiconductor component can be intended for generating or emitting electromagnetic radiation.

In the case of radiation-emitting semiconductor components based on an InGaAlP compound semiconductor material, for example, there are various possibilities for electrical contacting. For example, a first electrode of a first polarity, such as a p-electrode, can be arranged on a rear side and a second electrode of a second polarity, such as an n-electrode, can be arranged on a front side. However, due to the arrangement of the second electrode on the front side, which is intended for radiation emission, absorption losses occur there. Alternative concepts provide for vias that completely penetrate the semiconductor chip and extend to the front side. In this case, the second electrode, albeit smaller in size, is again arranged on the front side and can therefore also lead to absorption losses. It would also be possible to electrically contact a semiconductor region arranged on the front side from the rear side by means of one or more vias that lead through the semiconductor chip. However, due to relatively high tolerances in the production of depressions in which the vias are generated, a semiconductor layer that is to be contacted by means of the via(s) would have to be as thick as possible, which in turn would result in relatively high absorption losses due to its thickness and possibly high doping.

One of the objects to be achieved by the present disclosure, inter alia, is to specify a more efficient optoelectronic semiconductor component. A further object to be achieved by the present disclosure, inter alia, is to specify a method for producing at least one optoelectronic semiconductor component of higher efficiency.

These objects are achieved, inter alia, by an optoelectronic semiconductor component and a method for producing at least one optoelectronic semiconductor component having the features of the independent claims.

Further advantages and configurations of an optoelectronic semiconductor component and of a method for producing an optoelectronic semiconductor component are the subject of the dependent claims.

According to at least one embodiment of an optoelectronic semiconductor component, the semiconductor component comprises a semiconductor layer stack comprising a first semiconductor region, a second semiconductor region, and an active zone which is arranged between the first and second semiconductor regions. The active zone can be intended for generating or emitting electromagnetic radiation, for example in the visible to infrared spectral range.

Furthermore, the active zone can comprise a sequence of individual layers. By means of the individual layers, a quantum well structure, in particular a single quantum well (SQW) structure or multiple quantum well (MQW) structure, can be formed.

The first semiconductor region can have a first conductivity type, for example a p-conductivity. Furthermore, the second semiconductor region may have a second conductivity type, for example an n-conductivity. However, it is also possible that the second semiconductor region is a p-conducting semiconductor region and the first semiconductor region is an n-conducting semiconductor region. The first and second semiconductor regions can each comprise a sequence of individual layers, some of which can be undoped or lightly doped. The individual layers can be layers epitaxially deposited on a growth substrate.

According to at least one embodiment, the second semiconductor region comprises a first semiconductor layer comprising a first compound semiconductor material and a second semiconductor layer comprising a second compound semiconductor material different from the first compound semiconductor material. The first compound semiconductor material may have a higher aluminum content than the second compound semiconductor material. When choosing a suitable etching agent with sufficient selectivity, the higher aluminum content in the first semiconductor layer leads to a higher etching rate than in the second semiconductor layer. As a result, the etching process can be stopped at the second semiconductor layer. This makes it possible to set an etching depth particularly precisely or to determine the vertical extension of a depression to be generated with comparatively high precision.

According to at least one embodiment, the second semiconductor layer is arranged on a side of the first semiconductor layer facing away from the active zone.

According to at least one embodiment, the optoelectronic semiconductor component comprises at least one depression extending from a first main surface of the semiconductor layer stack through the first semiconductor region and the active zone and ending at the second semiconductor layer. The first main surface may be a surface of the semiconductor layer stack delimiting the latter on a side facing a rear side of the optoelectronic semiconductor component.

According to at least one embodiment, the optoelectronic semiconductor component comprises a first contact structure for electrically contacting the first semiconductor region and a second contact structure for electrically contacting the second semiconductor region. The first contact structure can be arranged at least in some areas at the first main surface. Furthermore, the second contact structure can be arranged in some areas at the first main surface and in the at least one depression. By means of the first and second contact structures, it is possible to electrically connect the optoelectronic semiconductor component from the outside on only one side of the semiconductor component, for example on a side flank. The first and second contact structures enable a homogeneous current distribution in the semiconductor layer stack, so that larger semiconductor components can be realized as well.

According to at least one embodiment of an optoelectronic semiconductor component, the optoelectronic semiconductor component comprises:
a semiconductor layer stack comprising
   a first semiconductor region,
   a second semiconductor region, and
   an active zone which is arranged between the first and second semiconductor regions, wherein the second semiconductor region comprises a first semiconductor layer and a second semiconductor layer, and the second semiconductor layer is arranged on a side of the first semiconductor layer facing away from the active zone,
at least one depression which extends from a first main surface of the semiconductor layer stack through the first semiconductor region and the active zone and ends at the second semiconductor layer,
a first contact structure for electrically contacting the first semiconductor region, said first contact structure being arranged at least in some areas at the first main surface,
a second contact structure for electrically contacting the second semiconductor region, said second contact structure being arranged in some areas at the first main surface and in the at least one depression,
   wherein the first semiconductor layer comprises a first compound semiconductor material and the second semiconductor layer comprises a second compound semiconductor material, and the first compound semiconductor material has a higher aluminum content than the second compound semiconductor material.

For example, the at least one depression or a contact region of the second contact structure arranged in the depression can have a three-dimensional shape with an invariable cross-section, for example the shape of a cylinder or cuboid.

However, it is also possible for the at least one depression or the contact region arranged in the depression to have a three-dimensional shape with a variable cross-section, for example the shape of a truncated cone or truncated pyramid. The cross-section can become smaller with increasing depth. For example, the shape and size of the contact region are determined by the shape and size of the depression. The shape and size of the contact region can at least approximately resemble the shape and size of the depression.

If a plurality of depressions or contact regions are present, these can vary in size and/or their mutual spacing, for example to compensate for a contact resistance and/or surface resistance in the second semiconductor region.

According to at least one embodiment or configuration, the first compound semiconductor material is a phosphide compound semiconductor material, i.e. a semiconductor material with a phosphorus content. Furthermore, the second compound semiconductor material can also be a phosphide compound semiconductor material. InGaAlP can be used for the first and second phosphide compound semiconductor materials.

According to at least one embodiment or configuration, the first compound semiconductor material comprises AlₙGaₘIn₁₋ₙ₋ₘP, where 0.3≤n≤0.6, 0≤m≤0.2, and 0.4≤n+m≤0.6. The first semiconductor layer can have the function of a buffer layer. A suitable lattice constant can be achieved with an indium content of between 40% and 60%.

According to at least one embodiment or configuration, the second compound semiconductor material comprises AlₙGaₘIn₁₋ₙ₋ₘP, where 0<n<0.6, 0<m<0.6, and 0.4≤n+m≤0.6. The second semiconductor layer can, for example, have the function of a contact layer or a contact and current spreading layer. The second semiconductor layer can be formed thinner than the first semiconductor layer. For example, the second semiconductor layer can have a thickness of between 10 nm and 500 nm, in particular between 20 nm and 100 nm, with manufacturing tolerances of ±10% being possible. Due to the comparatively low thickness, relatively few absorption losses occur in the second semiconductor layer or contact layer.

According to at least one embodiment or configuration, the second semiconductor region comprises a third semiconductor layer, which is arranged on a side of the second semiconductor layer facing away from the first semiconductor layer. As for the first and second semiconductor layers, a phosphide compound semiconductor material, in particular InGaAlP, is suitable for the third semiconductor layer. The compound semiconductor materials of the second and third semiconductor layers can differ in their gallium content and/or the level of their doping. For example, as already mentioned above, the second semiconductor layer can be a contact layer and the third semiconductor layer can be a current spreading layer.

According to at least one embodiment or configuration, a second main surface of the semiconductor layer stack opposite the first main surface is free of the first and second contact structures. The second main surface may be located on a front side of the optoelectronic semiconductor component intended for radiation emission. A substantial portion of the radiation to be emitted may pass through the second main surface and would be partially absorbed at contact structures arranged on the second main surface. This can advantageously be prevented by arranging the contact structures outside the second main surface.

According to at least one embodiment or configuration, the at least one depression has a widened region between the active zone and the second semiconductor layer. The widened region can be taken as an indication of a two-step etching process for producing the at least one depression, as described in more detail below in connection with the production method.

For example, the widened region may have a depth or vertical extension that corresponds at least approximately to at least 25% of a thickness of the first semiconductor layer and at most to the thickness of the first semiconductor layer. The vertical extension can denote an extension along a vertical direction which, for example, runs antiparallel to a growth direction in which the semiconductor regions are grown on top of each other. In addition, the widened region may have a lateral extension that deviates by about 10% with tolerances of ±10% from an expected lateral extension at the bottom of the depression that would be obtained if the original shape of the depression were continued. For example, values between 5.5 μm and 7.5 μm with tolerances of ±10% are possible values for the lateral extension of the widened region.

According to at least one embodiment or configuration, the second contact structure comprises a connecting layer. The connecting layer can cover one or more surfaces of the semiconductor layer stack delimiting the at least one depression. Material compounds and/or layer stacks that are metallic are suitable for the connecting layer. For example, Au or Pd are suitable for the connecting layer. The connecting layer can have a dopant such as Ge.

According to at least one embodiment or configuration, there is a cavity in the widened region of the at least one depression between the semiconductor layer stack and the second contact structure. The cavity can be gas-filled or essentially unfilled, so that a vacuum exists therein. For example, the course of the connecting layer and any other layers applied to the semiconductor layer stack in the widened region can continue to follow the original shape of the depression, which it would have if it were continued without a widened region. Since it is therefore possible that the second contact structure or the connecting layer and, if applicable, the other layers is/are not conformally applied to the semiconductor layer stack in the widened region of the depression, a cavity may be created.

According to at least one embodiment or configuration, the optoelectronic semiconductor component comprises an insulating layer arranged between the semiconductor layer stack and the connecting layer. The insulating layer may comprise an electrically insulating material, such as silicon oxide or silicon nitride, or may consist of one of these materials. For example, the insulating layer may be arranged on one or more surface(s) of the semiconductor layer stack laterally delimiting the depression. The surface at the bottom of the depression can be uncovered by the insulating layer, so that the second semiconductor layer can be contacted by the second contact structure or by the connecting layer.

According to at least one embodiment or configuration, the optoelectronic semiconductor component comprises a carrier on which the semiconductor layer stack is arranged. The first semiconductor region may be arranged on a side of the active zone facing towards the carrier, and the second semiconductor region may be arranged on a side of the active zone facing away from the carrier. The carrier may contain or consist of a semiconductor material such as Ge or Si or a ceramic material such as SiN.

The method described below is suitable for the production of at least one optoelectronic semiconductor component as described above. Features described in connection with the semiconductor component are therefore also applicable to the method and vice versa.

According to at least one embodiment or configuration of a method for producing at least one optoelectronic semiconductor component, the method comprises the following steps, for example in the order indicated:
providing a semiconductor layer sequence for producing at least one semiconductor layer stack, the semiconductor layer sequence comprising:
   a first semiconductor region,
   a second semiconductor region,
   an active zone which is arranged between the first and second semiconductor regions, wherein the second semiconductor region comprises a first semiconductor layer and a second semiconductor layer, and the second semiconductor layer is arranged on a side of the first semiconductor layer facing away from the active zone, and
   a first main surface,
forming a first contact structure on the first main surface,
generating at least one depression which extends from the first main surface through the first semiconductor region and the active zone and ends at the second semiconductor layer,
forming a second contact structure which is arranged in some areas at the first main surface and in the at least one depression, wherein
the at least one depression is generated by a two-step etching process, and the semiconductor layer sequence is etched in a first etching step down into the first semiconductor layer and in a second etching step down to the second semiconductor layer.

In contrast to a single-step etching process, in which the end of the etching process or the etching depth can be controlled less precisely than in a two-step etching process as described here, so that the semiconductor layer in which the etching process is to stop must be formed comparatively thick, the second semiconductor layer here can be formed comparatively thin, for example with a thickness between 10 nm and 500 nm, in particular between 20 nm and 100 nm, with typical manufacturing tolerances of ±10% being possible. In contrast, the first semiconductor layer, in which the first etching step ends, can be formed thicker than the second semiconductor layer. For example, the thickness of the first semiconductor layer can be between 0.4 μm and 0.6 μm with tolerances of ±10%. The thickness of the first semiconductor layer takes account of, for example, the thickness and etching rate fluctuations that occur during the first etching step.

The semiconductor layer sequence corresponds, for example in terms of its layer structure and its material composition, to the semiconductor layer stack which is produced from it, so that the specifications made in this regard apply accordingly to the semiconductor layer sequence. Preferably, the first semiconductor region of the at least one semiconductor layer stack is formed from the first semiconductor region of the semiconductor layer sequence, the active zone of the at least one semiconductor layer stack is formed from the active zone of the semiconductor layer sequence, and the second semiconductor region of the at least one semiconductor layer stack is formed from the second semiconductor region of the semiconductor layer sequence. In particular, the first semiconductor layer of the second semiconductor region is formed from a first compound semiconductor material, for example InAlP, and the second semiconductor layer is formed from a second compound semiconductor material, for example InGaAlP, wherein the first compound semiconductor material has a higher aluminum content than the second compound semiconductor material.

The semiconductor layer sequence can be provided on a substrate on which it has been grown epitaxially, for example.

Furthermore, the first and second contact structures formed on the semiconductor layer sequence are designed such that a first and a second contact structure for at least one optoelectronic semiconductor component can be produced therefrom. Therefore, the specifications made in connection with the first and second contact structures of the optoelectronic semiconductor component, for example with regard to their structure and suitable materials, apply accordingly. In particular, the second contact structure can comprise a connecting layer, which is provided for producing a connecting layer of the second contact structure of at least one semiconductor component. The connecting layer may cover one or more surfaces of the semiconductor layer sequence delimiting the at least one depression.

According to at least one embodiment or configuration, the first etching step comprises a dry etching process. Furthermore, the second etching step may comprise a wet chemical etching process. For the second etching step or wet chemical etching process, in particular an etching agent with sufficient selectivity is used, which has a higher etching rate for the first semiconductor layer having a higher aluminum content than for the second semiconductor layer having a lower aluminum content. For example, the etching rate in the second semiconductor layer can be more than one order of magnitude lower than in the first semiconductor layer. This allows the etching process to be terminated specifically at the second semiconductor layer. The desired etching depths can thus be set in a targeted manner.

Aqueous solutions, for example diluted hydrochloric acid or diluted sulphuric acid, can be used as etching agents.

According to at least one embodiment or configuration, a widened region of the at least one depression is generated by means of the second etching step. The widened region is created by under-etching in the first semiconductor layer. With regard to the size of the widened region, reference is made to the specifications already made in connection with the optoelectronic semiconductor component.

According to at least one embodiment or configuration, an insulating layer is formed between the semiconductor layer sequence and the connecting layer, said insulating layer being provided for producing an insulating layer in at least one semiconductor component. Therefore, the specifications made in connection with the insulating layer of the optoelectronic semiconductor component, for example with regard to its structure and suitable materials, apply accordingly. For example, the insulating layer can be applied to the semiconductor layer sequence as a closed layer, so that the surfaces delimiting the depression or a first partial region of the depression are completely covered. The insulating layer can then be partially removed so that a surface of the semiconductor layer sequence arranged at the bottom of the depression or the first partial region of the depression is exposed.

According to at least one embodiment or configuration, the insulating layer is applied before the second etching step is performed. In this case, the insulating layer may be under-etched during the second etching step and may have a distance to the semiconductor layer sequence. However, it is also possible for the insulating layer to be applied after the second etching step. In this case, the insulating layer may be closer to the semiconductor layer sequence.

According to at least one embodiment or configuration, the active zone comprises a quantum well structure, wherein intermixing of the quantum well structure is performed in some areas of the active zone adjacent to the depression. In this process, quantum wells and barrier layers are intermixed so that a higher band gap occurs, resulting in fewer charge carriers and surface recombination. The intermixing can take place before layers, for example the insulating layer or connecting layer, are applied to the semiconductor layer sequence in the depression. It is also possible to perform the intermixing before the depression is generated.

The optoelectronic semiconductor component is suitable for projection and lighting applications, for example in the longer wavelength spectral range, such as red to infrared.

Further advantages, advantageous embodiments and further developments will become apparent from the exemplary embodiments described below in conjunction with the figures.

### IN THE FIGURES

FIGS. 1 to 11 show schematic cross-sectional views of various method steps of a method for producing an optoelectronic semiconductor component according to an exemplary embodiment, and

FIG. 12 shows a schematic cross-sectional view of an optoelectronic semiconductor component according to an exemplary embodiment.

In the exemplary embodiments and figures, identical elements, elements of the same kind or elements having the same effect may be provided with the same or similar reference signs, which differ from each other only by an inverted comma. The elements shown and their relative sizes are not necessarily to be regarded as true to scale; rather, individual elements may be shown in exaggerated size for better visualization and/or understanding.

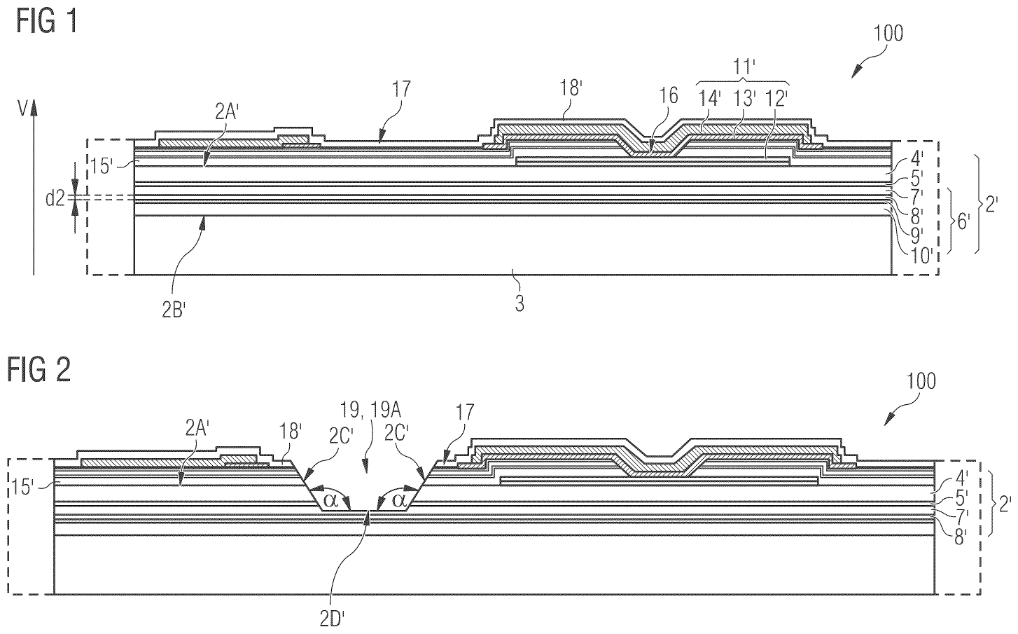

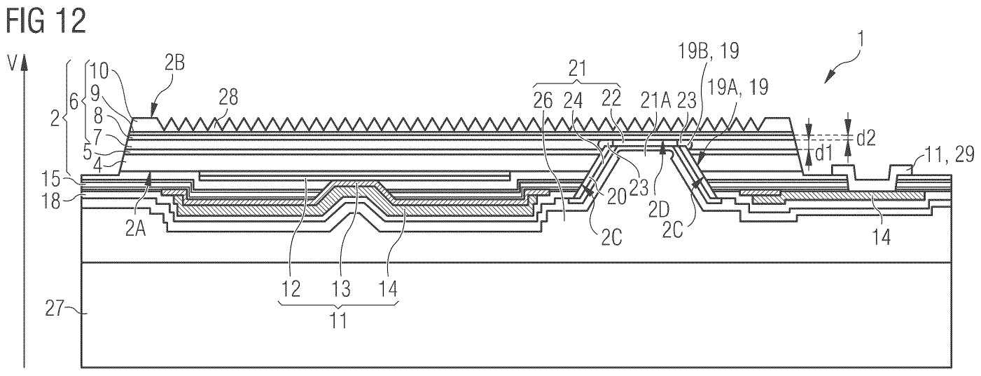

FIGS. 1 to 11 are used to describe an exemplary embodiment of a method or a layer composite 100 which is suitable for producing an optoelectronic semiconductor component 1 as described below, for example in connection with FIG. 12, as well as possible variants of the exemplary embodiment. The dashed areas in the figures symbolize further areas of the layer composite 100 which, for example, enable the production of a plurality of optoelectronic semiconductor components 1.

The method comprises a step of providing a semiconductor layer sequence 2′ for producing at least one semiconductor layer stack 2 (see FIG. 12), wherein the semiconductor layer sequence 2′ is provided on a substrate 3 (see FIG. 1). The semiconductor layer sequence 2′ can be formed from semiconductor materials based on phosphide compound semiconductors. Furthermore, the substrate 3 can be formed from a semiconductor material based on an arsenide compound semiconductor. For example, GaAs can be used for the substrate 3. In particular, the substrate 3 is a growth substrate on which the semiconductor layer sequence 2′ is epitaxially deposited.

The semiconductor layer sequence 2′ comprises a first semiconductor region 4′ of a first conductivity type, for example a p-conductivity, a second semiconductor region 6′ of a second conductivity type, for example an n-conductivity, and an active zone 5′, which is arranged between the first and second semiconductor regions 4′, 6′. The first semiconductor region 4′ is located on a side of the active zone 5′ facing away from the substrate 3, while the second semiconductor region 6′ is located between the substrate 3 and the active zone 5′.

The first and second semiconductor regions 4′, 6′ can each comprise a sequence of individual layers, which can be doped, but in some cases also undoped or lightly doped. For example, the first semiconductor region 4′ can comprise a confinement layer near the active zone 5′ (not shown). Furthermore, the second semiconductor region 6′ comprises a first semiconductor layer 7′ and a second semiconductor layer 8′, which is arranged on a side of the first semiconductor layer 7′ facing away from the active zone 5′. The second semiconductor layer 8′ can be designed in such a way that it assumes the function of a contact and current spreading layer. However, it is also possible for the different functions to be realized by different layers. In the exemplary embodiment shown, the second semiconductor layer 8′ has the function of a contact layer. For the function of a current spreading layer, a third semiconductor layer 9′ is provided, which is located on a side of the second semiconductor layer 8′ facing away from the first semiconductor layer 7′. Furthermore, the second semiconductor region 6′ can have a radiation exit layer 10′, which is arranged on a side of the semiconductor layer sequence 2′ facing the substrate 3 and can be provided with a radiation outcoupling structure to improve the radiation emission in the finished semiconductor component.

Furthermore, the active zone 5′ can comprise a sequence of individual layers. A quantum well structure, in particular a single quantum well (SQW) structure or multiple quantum well (MQW) structure, can be formed by means of the individual layers.

The first semiconductor layer 7′ of the second semiconductor region 6′ may be formed from a first phosphide compound semiconductor material and the second semiconductor layer 8′ may be formed from a second phosphide compound semiconductor material, wherein the first compound semiconductor material has a higher aluminum content than the second compound semiconductor material. In particular, the first compound semiconductor material comprises AlₙGaₘIn₁₋ₙ₋ₘP, where 0.3≤n≤ 0.6, 0≤m≤0.2, and 0.4≤n+m≤0.6. The first semiconductor layer 7′ can have the function of a buffer layer. A suitable lattice constant can be achieved with an indium content of between 40% and 60%. Furthermore, the second compound semiconductor material can comprise AlₙGaₘIn₁₋ₙ₋ₘP, where 0<n<0.6, 0<m<0.6, and 0.4≤n+m≤0.6. The third semiconductor layer 9′ can, like the first and second semiconductor layers 7′, 8′, be formed from a phosphide compound semiconductor material, in particular from InGaAlP, wherein the compound semiconductor materials of the second and third semiconductor layers 8′, 9′ differ in their gallium content and/or the level of their doping.

The second semiconductor layer 8′ can be formed thinner than the first semiconductor layer 7′. For example, the second semiconductor layer 8′ can have a thickness d2 between 10 nm and 500 nm, in particular between 20 nm and 100 nm, with typical manufacturing tolerances of ±10% being possible. Due to the comparatively low thickness d2, absorption losses can be reduced in the second semiconductor layer 8′ or contact layer. The thickness can denote a vertical extension along a vertical direction V which, for example, runs parallel to a growth direction in which the semiconductor regions 6′, 5′, 4′ are grown on top of each other.

Furthermore, the method comprises a step of forming a first contact structure 11′ on a first main surface 2A′ of the semiconductor layer sequence 2′, wherein the first main surface 2A′ delimits the semiconductor layer sequence 2′ outwardly on a side facing away from the substrate (see FIG. 1). The step of forming the first contact structure 11′ may include generating a first spreading layer 12′ on the first main surface 2A′. The first spreading layer 12′ can be applied in direct contact with the first semiconductor region 4′. The first spreading layer 12′ can be formed as a monolayer or multilayer. For example, TCOs (transparent conductive oxides) such as ITO, Zno, InZnO or Alo are suitable for the first spreading layer 12′.

Furthermore, the step of forming the first contact structure 11′ may include generating a second spreading layer 14′, which is arranged on a side of the first spreading layer 12′ facing away from the semiconductor layer sequence 2′ and is electrically conductively connected thereto. The second spreading layer 14′ can cover a larger area of the first main surface 2A′ than the first spreading layer 12′. For example, the second spreading layer 14′ is a metallic layer, which can be formed as a monolayer or multilayer.

Furthermore, the step of forming the first contact structure 11′ may include generating a mirror layer 13′, for example formed of Ag, between the first and second spreading layers 12′, 14′. While in operation of the finished semiconductor component 1 (see FIG. 12) radiation emitted by the active zone 5′, 5 can be transmitted to a substantial extent through the first spreading layer 12′, 12, it is possible by means of the mirror layer 13′, 13 to deflect the emitted radiation in the direction of a second main surface 2B′, 2B opposite the first main surface 2A′, 2A and to shield the second spreading layer 14′, 14, at which absorption can occur, against the radiation.

To achieve an advantageous reflectivity on the rear side of the finished semiconductor component, a reflective element 15′ can be arranged on the first main surface 2A′ (see FIG. 1). The reflective element 15′ may have alternately arranged layers of a higher and a lower refractive index. The layers can be dielectric layers, for which materials such as SioO, SiN, NbO or HfO are suitable. For example, the reflective element 15′ comprises a Bragg mirror. The reflective element 15′ may cover the first main surface 2A′ while partially covering the first spreading layer 12′. The reflective element 15′ can be provided with an opening 16, into which the second spreading layer 14′ and, where applicable, the mirror layer 13′ extend as far as the first spreading layer 12′.

Furthermore, an opening 17 can be formed in the second spreading layer 14′ and, where applicable, in the mirror layer 13′ at a lateral distance from the opening 16.

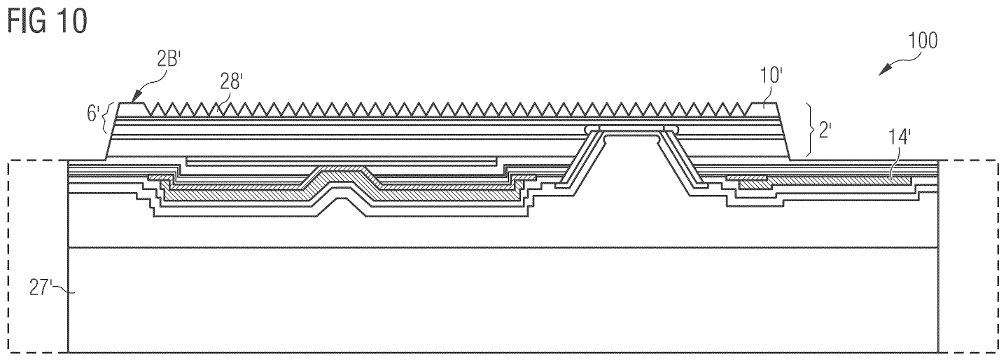

On a side of the second spreading layer 14′ facing away from the semiconductor layer sequence 2′, an insulation layer 18′ can be applied, which covers the first main surface 2A′ at least for the most part and extends into the opening 17. The insulation layer 18′ is intended to electrically insulate the first contact structure 11′ and a second contact structure 21′ (see FIG. 10) on the first main surface 2A′ from one another.

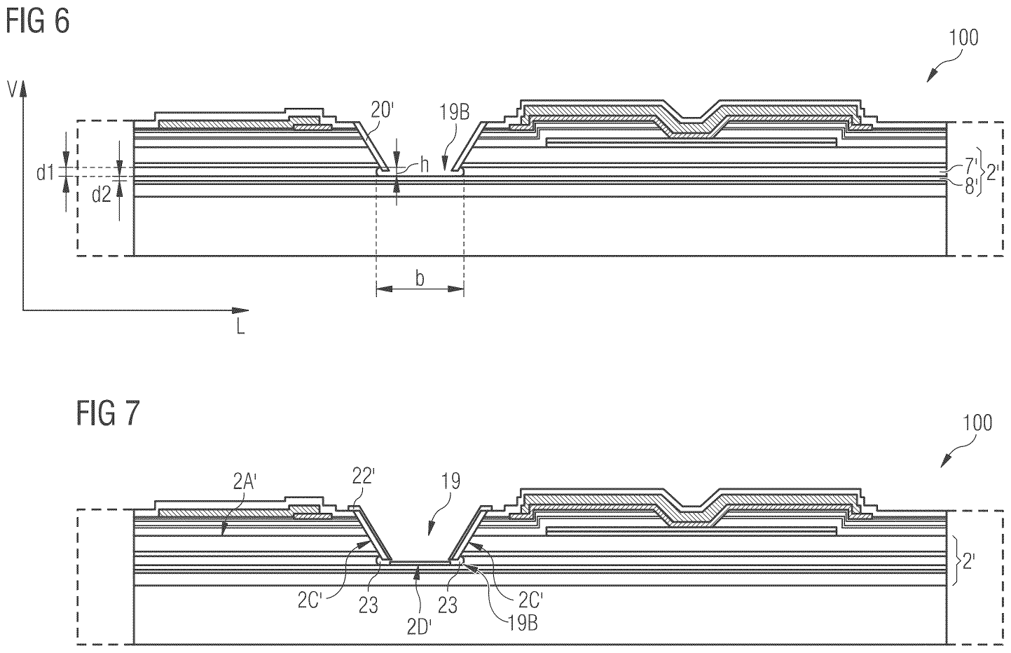

As shown in FIGS. 2 and 6, the method further comprises a step of generating at least one depression 19 extending from the first main surface 2A′ through the first semiconductor region 4′ and the active zone 5′ and ending at the second semiconductor layer 8′. The depression 19 can already begin at the insulation layer 18′ and extend through the opening 17.

The depression 19 is generated by a two-step etching process. In a first etching step, the semiconductor layer sequence 2′ is etched down into the first semiconductor layer 7′. The first etching step comprises, for example, a dry etching process. A first region 19A of the depression 19 produced in this process is laterally delimited by one or more surfaces 2C′ of the semiconductor layer sequence 2′, which in cross-section can each extend at an angle of 90°<α<180°, in particular 95°<α<115°, to a surface 2D′ of the semiconductor layer sequence 2′ delimiting the first region 19A at the bottom (see FIG. 2). The first region 19A can have the shape of a truncated cone or truncated pyramid.

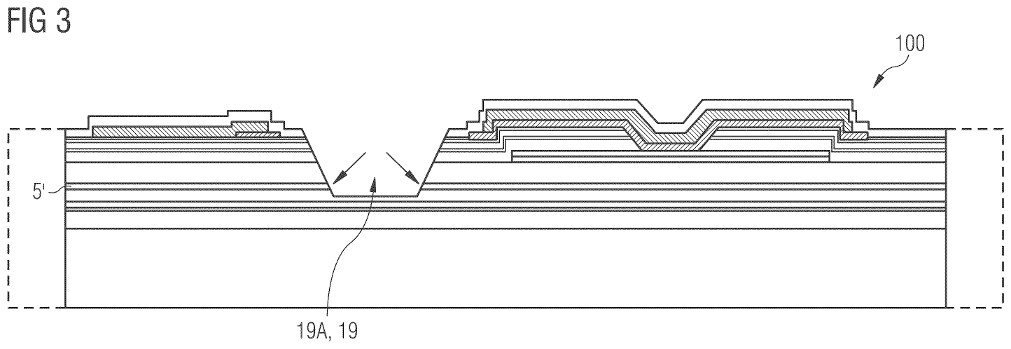

Furthermore, as indicated by arrows in FIG. 3, the method may include a step of intermixing the quantum well structure of the active zone 5′ in areas adjacent to the depression 19 or to the first region 19A of the depression 19. In this step, quantum wells and barrier layers are intermixed, for example thermally, if applicable by introducing contaminations, so that a higher band gap occurs, resulting in fewer charge carriers and surface recombination. This step is carried out, for example, if surface recombinations play a role in the depression 19. The intermixing takes place in particular at an early stage, for example even before the depression 19 is generated, so that higher temperatures are also possible.

Furthermore, the method may include a step of generating an insulating layer 20′, which is carried out before the second etching step like in this exemplary embodiment. However, it is also possible for this step to be carried out after the second etching step.

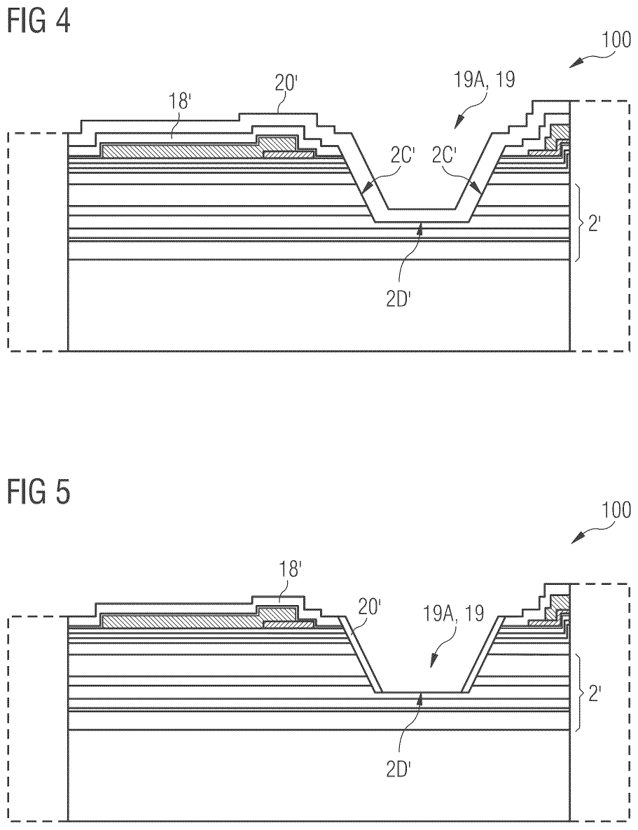

As shown in FIG. 4, the insulating layer 20′ is applied, for example, as a closed layer to the semiconductor layer sequence 2′, so that the surfaces 2C′, 2D′ delimiting the first region 19A of the depression 19 are completely covered. The insulating layer 20′ is then partially removed, so that the surface 2D′ of the semiconductor layer sequence 2′ arranged at the bottom of the first region 19A of the depression 19 is exposed (see FIG. 5).

The insulating layer 20′ can be formed from an electrically insulating material such as silicon oxide or silicon nitride or from a combination of these materials.

After structuring of the insulating layer 20′, the second etching step takes place, as shown in FIG. 6, wherein the semiconductor layer sequence 2′ is etched down to the second semiconductor layer 8′. For example, the second etching step comprises a wet chemical etching process. For the second etching step or wet chemical etching process, in particular an etching agent with sufficient selectivity is used, which has a higher etching rate for the first semiconductor layer 7′ having a higher aluminum content than for the second semiconductor layer 8′ having a lower aluminum content. For example, the etching rate in the second semiconductor layer 8′ can be more than one order of magnitude lower than in the first semiconductor layer 7′. This allows the etching process to be terminated precisely at the second semiconductor layer 8′, so that desired etching depths can be specifically set. Aqueous solutions, for example dilute hydrochloric acid or dilute sulphuric acid, can be used as etching agents.

In contrast to a less precise, one-step etching process, in which the semiconductor layer to be contacted must be formed comparatively thick due to the higher tolerances, the second semiconductor layer 8′ to be contacted can be formed comparatively thin with a thickness d2 between 10 nm and 500 nm, in particular between 20 nm and 100 nm, with typical manufacturing tolerances of ±10% being possible. In contrast, the first semiconductor layer 7′, in which the first etching step ends, can be formed thicker than the second semiconductor layer 8′. For example, values between 0.4 μm and 0.6 μm with tolerances of ±10% are possible for the thickness d1 of the first semiconductor layer 7′. The thickness d1 of the first semiconductor layer 7′ takes account of, for example, the thickness and etching rate fluctuations that occur during the first etching step.

In the second etching step, a widened region 19B of the depression 19 is generated. The widened region 19B is created by under-etching in the first semiconductor layer 7′. The insulating layer 20′ is also under-etched in the second etching step, so that it has a distance to the semiconductor layer sequence 2′.

For example, the widened region 19B can have a depth or vertical extension h that corresponds at least approximately to at least 25% of the thickness d1 of the first semiconductor layer 7′ and at most to the thickness d1. The vertical extension h can denote an extension along the vertical direction V.

In addition, the widened region 19B can have a lateral extension b that deviates by about 10% with tolerances of ±10% from an expected lateral extension at the bottom of the depression 19 that would be achieved if the original shape of the depression 19 were continued or if the shape of the first region 19A of the depression 19 were continued while maintaining the angle α (see FIG. 2). For example, values between 5.5 μm and 7.5 μm with tolerances of ±10% can be considered for the lateral extension b of the widened region. The lateral extension b can denote an extension along a lateral direction L, which runs transverse, for example perpendicular to the direction V.

The method further comprises a step of forming a second contact structure 21′, which is arranged in some areas at the first main surface 2A′ and in the depression 19 (see FIGS. 7 to 9).

The step of forming the second contact structure 21′ may comprise generating a connecting layer 22′ that cover one or more surfaces 2C′, 2D′ of the semiconductor layer sequence 2′ delimiting the depression 19 (see FIG. 7). For example, the connecting layer 22′ can cover only the surface 2D′ arranged at the bottom of the depression 19 or additionally the surfaces 2C′. In particular, the connecting layer 22′ is applied in such a way that the second semiconductor layer 8′ can be electrically contacted through it. The connecting layer 22′ can be produced from one or more material compounds and/or a layer sequence of materials that are metallic. For example, materials or material compounds that contain Au or Pd and are doped with Ge, for example, are suitable for the connecting layer 22′. Surface oxides can be removed before applying the connecting layer 22′. After applying the connecting layer 22′, a so-called annealing process can be carried out.

As can be seen from FIG. 7, in the widened region 19B of the depression 19 between the semiconductor layer sequence 2′ and the insulating layer 20′ or connecting layer 22′ there is a cavity 23, which is essentially unfilled, for example, so that a vacuum exists therein, or which is filled with gas. This cavity can be created by the insulating layer 20′ or connecting layer 22′ in the widened region 19B continuing to follow the original shape of the depression 19 or the shape of the first region 19A of the depression 19.

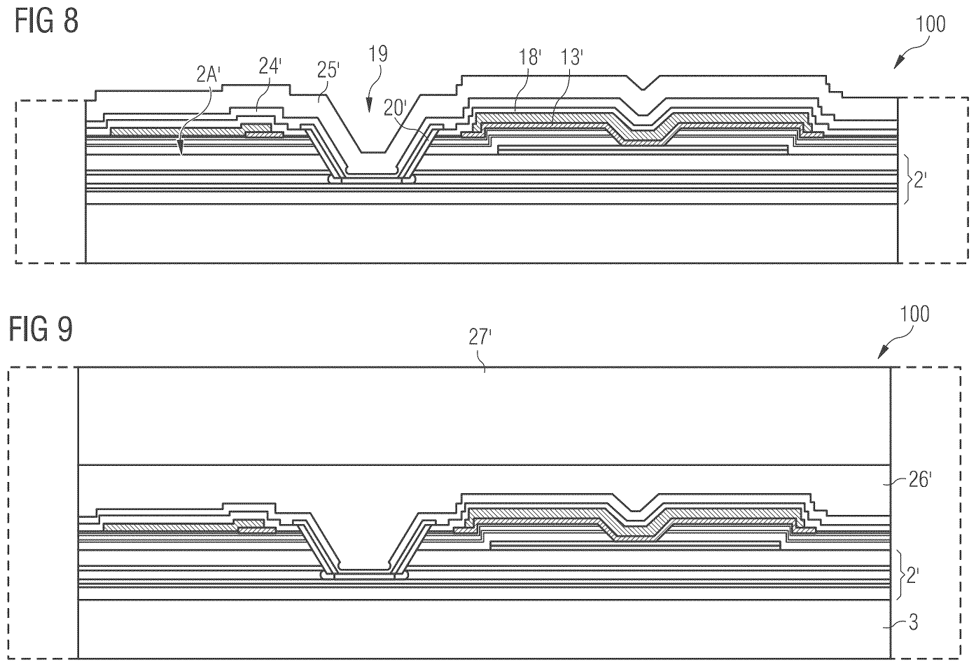

As shown in FIG. 8, the step of forming the second contact structure 21′ may further comprise forming a solder barrier layer 24′ and forming a first solder layer 25′, wherein the solder barrier layer 24′ is arranged between the semiconductor layer sequence 2′ and the first solder layer 25′. The solder barrier layer 24′ is intended to prevent solder material from diffusing into the layers 2′, 13′ 18′, 20′, for example. The solder barrier layer 24′ and the first solder layer 25′ can cover the first main surface 2A′ and also fill the depression 19. Suitable materials for the solder barrier layer 24′ are, for example, WTi, Ti or Ta. Suitable materials for the first solder layer 25′ are, for example, AuPt, Au or Ni.

Furthermore, the step of forming the second contact structure 21′ may comprise forming a second solder layer (not shown) on the first solder layer 25′, which bonds to the first solder layer 25′ when bonded to a carrier 27′, so that a bonding layer 26′ is formed (see FIG. 9). Suitable materials for the second solder layer are, for example, Sn and InSn, so that the bonding layer 26′ contains, for example, AuSn, AuInSn, NiSn or NiInSn. The carrier 27′ can be formed from a semiconductor material such as Ge or Si or a ceramic material such as SiN. The carrier 27′ is applied to a side of the semiconductor layer sequence 2′ facing away from the substrate 3.

The method may further comprise a step of removing the substrate 3 (see FIG. 10). In this process, the second main surface 2B′ of the semiconductor layer sequence 2′ can be exposed. For example, the substrate 3 may be removed by wet chemical etching. Further, the method may include a step of forming a radiation outcoupling structure 28′ in the radiation exit layer 10′. For example, the radiation outcoupling structure 28′ can be generated by roughening a surface of the radiation exit layer 10′ facing away from the carrier 27′ or by roughening the second semiconductor region 6′ on the second main surface 2B′. The roughening can be carried out, for example, by means of a lithographic method and a dry etching process.

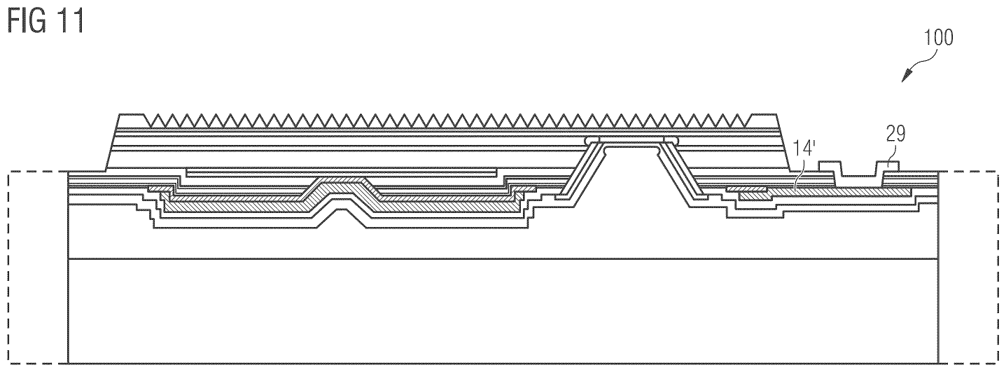

The method may further comprise a step of structuring the semiconductor layer sequence 2′ (see FIG. 10). For example, the structuring can be performed by dry etching. During structuring, edge regions of the semiconductor layer sequence 2′ can be removed so that, for example, the second spreading layer 14′ protrudes at least in some areas beyond the semiconductor layer sequence 2′ and can be brought into contact, in the protruding region, with a contact pad 29, which is formed from Au, for example (see FIG. 11). The semiconductor layer sequence 2′ can be structured in such a way that it has a mesa-like shape, and the carrier 27′ protrudes beyond the semiconductor layer sequence 2′ on all sides when viewed from above.

With reference to FIG. 12, an exemplary embodiment of an optoelectronic semiconductor component 1 is described, which can be produced by means of a method as described in connection with FIGS. 1 to 11, wherein the optoelectronic semiconductor component 1 is singulated after the step shown in FIG. 11 by detaching it from the layer composite 100 between the dashed areas. Features and relationships described in connection with the method therefore apply accordingly to the optoelectronic semiconductor component 1 and vice versa.

The optoelectronic semiconductor component 1 comprises a carrier 27 and a semiconductor layer stack 2 arranged thereon, wherein the carrier 27 of the optoelectronic semiconductor component 1 emerges from the carrier 27′ (see FIG. 11) by a singulation process, and the semiconductor layer stack 2 corresponds to the structured semiconductor layer sequence 2′ (see FIG. 11).

Corresponding to the semiconductor layer sequence 2′, the semiconductor layer stack 2 comprises a first semiconductor region 4, a second semiconductor region 6, and an active zone 5 which is arranged between the first and second semiconductor regions 4, 6 and is intended for generating or emitting electromagnetic radiation, for example in the visible to infrared spectral range. Accordingly, the optoelectronic semiconductor component 1 can emit electromagnetic radiation during operation, for example in the visible to infrared spectral range. In this case, a substantial part of the radiation can be emitted at a second main surface 2B of the semiconductor layer stack 2, which is arranged on a front side of the semiconductor component 1.

Advantageously, the second main surface 2B is free of contact structures, so that no radiation losses caused by shading occur at the second main surface 2B. The optoelectronic semiconductor component 1 comprises a first contact structure 11 for electrically contacting the first semiconductor region 4, said first contact structure 11 being arranged in some areas at a first main surface 2A of the semiconductor layer stack 2. As explained in connection with FIG. 1, the first contact structure 11 may comprise a first spreading layer 12 arranged at the first main surface 2A and a second spreading layer 14 arranged between the first spreading layer 12 and the carrier 27. A mirror layer 13 can be arranged between the first and second spreading layers 12, 14 and also forms part of the first contact structure 11 if it has good electrical conductivity.

Furthermore, the optoelectronic semiconductor component 1 comprises a second contact structure 21 for electrically contacting the second semiconductor region 6, said second contact structure 21 being arranged in some areas at the first main surface 2A and in a depression 19 of the semiconductor layer stack 2. As already explained in more detail in connection with FIGS. 7 to 10, the second contact structure 21 can comprise a connecting layer 22 arranged in the depression 19, a bonding layer 26 adjoining the carrier 27, and a solder barrier layer 24 which is arranged on a side of the bonding layer 26 facing the semiconductor layer stack 2.

The first main surface 2A, which may for example be formed by a surface of the first semiconductor region 4, is arranged opposite the second main surface 2B, which may for example be formed by a surface of the second semiconductor region 6, and on a side of the semiconductor layer stack 2 facing the carrier 27. The first semiconductor region 4, for example a p-conducting region, may be arranged on a side of the active zone 5 facing the carrier 27. The second semiconductor region 6, for example an n-conducting region, may be arranged on a side of the active zone 5 facing away from the carrier 27.

As already described in connection with FIG. 1, the second semiconductor region 6 comprises a first semiconductor layer 7, which comprises a first compound semiconductor material with a higher aluminum content, and a second semiconductor layer 8, which comprises a second compound semiconductor material with a lower aluminum content that is different from the first compound semiconductor material. Each of the first and second compound semiconductor materials is a phosphide compound semiconductor material, for example. By means of the different aluminum content in the first and second semiconductor layers 7, 8, the two-step etching process for producing the depression 19 can be controlled so precisely that it stops in the second semiconductor layer 8, by means of which the second semiconductor region 6 is electrically contacted. Due to the comparatively low thicknesses d1, d2 (see the explanations relating to FIGS. 1 and 6), which are made possible by the precise, two-step etching process, an efficient semiconductor component 1 can be realized due to lower absorption, among other things. The first semiconductor layer 7 is arranged between the active zone 5 and the second semiconductor layer 8.

The depression 19, in which the second contact structure 21 is arranged in some areas, extends from the first main surface 2A of the semiconductor layer stack 2 through the first semiconductor region 4 and the active zone 5 and ends at the second semiconductor layer 8. For example, the depression 19 or a contact region 21A of the second contact structure 21 arranged in the depression 19 may have a three-dimensional shape with a variable cross-section, for example the shape of a truncated cone or truncated pyramid. The cross-section can become smaller with increasing depth, wherein the depth can be determined parallel to a vertical direction V in which the semiconductor regions 4, 5, 6 follow one another starting from the carrier 27. For example, the shape and size of the contact region 21A are determined by the shape and size of the depression 19. The shape and size of the contact region 21 may at least approximately resemble the shape and size of the depression 19. It is possible for the semiconductor component 1 to have more than one depression 19 or more than one contact region 21A if the contact and/or surface resistance is too high, and the plurality of depressions 19 or contact regions 21A can vary in their size and/or their mutual spacing.

The depression 19 has a widened region 19B between the active zone 5 and the second semiconductor layer 8. The widened region 19B can be interpreted as an indication of the two-step etching process. With regard to the vertical extension h and the lateral extension b of the widened region 19B, reference is made to the explanations in connection with FIG. 6.

In the widened region 19B, there is a cavity 23 between the semiconductor layer stack 2 and the second contact structure 21, said cavity 23 being substantially unfilled, for example, so that a vacuum exists therein, or being filled with air. For example, the course of the connecting layer 22 and other layers applied to the semiconductor layer stack 2, such as an insulating layer 20, can continue to follow the original shape of the depression 19 in the widened region 19B which it would have if it were continued without a widened region (see also the explanations relating to FIG. 2).

By means of the first and second contact structures 11, 21, it is possible to electrically connect the optoelectronic semiconductor component 1 from the outside on only one side of the semiconductor component 1. For example, a first contact pad 29 of the first contact structure 11, which serves as a first electrode of the semiconductor component 1, and a second contact pad (not shown) of the second contact structure 21, which serves as a second electrode of the semiconductor component 1, can be arranged laterally of the semiconductor layer stack 2 on a protruding region of the carrier 27 and can be provided for forming a connection to a contact means, for example a bonding wire.

The first contact pad 29 is arranged on a region not covered by the semiconductor layer stack 2, of a reflective element 15 arranged in some areas at the first main surface 2A and extends through an opening in the reflective element 15 to the second spreading layer 14 of the first contact structure 11. As already explained in more detail in connection with FIG. 1, the second spreading layer 14, like the mirror layer 13, extends through an opening 16 in the reflective element 15 to the first spreading layer 12.

The first contact structure 11 can be electrically insulated from the second contact structure 21 by means of the insulating layer 20 (in this respect see the explanations relating to FIGS. 4 to 6) and an insulation layer 18 (in this respect see the explanations relating to FIG. 1).

The first and second contact structures 11, 21 enable a homogeneous current distribution in the semiconductor layer stack 2, so that even larger semiconductor components can be realized.

The invention is not limited by the description based on the exemplary embodiments. Rather, the invention includes any new feature as well as any combination of features, which includes in particular any combination of features in the patent claims, even if this feature or combination itself is not explicitly stated in the patent claims or exemplary embodiments.

This patent application claims the priority of the German patent application 102022119108.7, the disclosure content of which is hereby incorporated by reference.

### REFERENCES

1 optoelectronic semiconductor component
2 semiconductor layer stack
2A first main surface
2B second main surface
2C, 2D surface
2′ semiconductor layer sequence
2A′ first main surface
2B′ second main surface
2C′, 2D′ surface
2E, 2E′ side surface
3 substrate
4, 4′ first semiconductor region
5, 5′ active zone
6, 6′ second semiconductor region
7, 7′ first semiconductor layer
8, 8′ second semiconductor layer
9 third semiconductor layer
10, 10′ radiation exit layer
11, 11′ first contact structure
12, 12′ first spreading layer
13, 13′ mirror layer
14, 14′ second spreading layer
15, 15′ reflective element
16, 17 opening
18, 18′ insulation layer
19 depression
19A first region
19B second, widened region
20, 20′ insulating layer
21, 21′ second contact structure
21A contact region
22, 22′ connecting layer
23 cavity
24, 24′ solder barrier layer
25′ first solder layer
26, 26′ bonding layer
27, 27′ carrier
28, 28′ radiation outcoupling structure
29 first contact pad
100 layer composite
α angle
b lateral extension
d1, d2 thickness
h depth, vertical extension
V vertical direction
L lateral direction

1. An optoelectronic semiconductor component comprising
a semiconductor layer stack comprising
a first semiconductor region,
a second semiconductor region, and
an active zone which is arranged between the first and second semiconductor regions, wherein the second semiconductor region comprises a first semiconductor layer and a second semiconductor layer, and the second semiconductor layer is arranged on a side of the first semiconductor layer facing away from the active zone,
at least one depression which extends from a first main surface of the semiconductor layer stack through the first semiconductor region and the active zone and ends at the second semiconductor layer,
a first contact structure for electrically contacting the first semiconductor region, said first contact structure being arranged at least in some areas at the first main surface,
a second contact structure for electrically contacting the second semiconductor region, said second contact structure being arranged in some areas at the first main surface and in the at least one depression,
wherein the first semiconductor layer comprises a first compound semiconductor material and the second semiconductor layer comprises a second compound semiconductor material, and the first compound semiconductor material has a higher aluminum content than the second compound semiconductor material.

2. The optoelectronic semiconductor component according to claim 1, wherein each of the first compound semiconductor material and the second compound semiconductor material is a phosphide compound semiconductor material.

3. The optoelectronic semiconductor component according to claim 1, wherein the first compound semiconductor material comprises AlₙGaₘIn₁₋ₙ₋ₘP, where 0.3≤n≤0.6, 0≤m≤0.2, and 0.4≤n+m≤0.6.

4. The optoelectronic semiconductor component according to claim 1, wherein the second compound semiconductor material comprises AlₙGaₘIn₁₋ₙ₋ₘP, where 0<n<0.6, 0<m<0.6, and 0.4≤n+m≤0.6.

5. The optoelectronic semiconductor component according to claim 1, wherein the second semiconductor layer is formed thinner than the first semiconductor layer.

6. The optoelectronic semiconductor component according to claim 1, wherein the second semiconductor region comprises a third semiconductor layer which is arranged on a side of the second semiconductor layer facing away from the first semiconductor layer and which contains InGaAlP, wherein the compound semiconductor materials of the second and third semiconductor layers differ in their gallium content and/or the level of their doping.

7. The optoelectronic semiconductor component according to claim 1, wherein a second main surface of the semiconductor layer stack opposite the first main surface is free of the first and second contact structures.

8. The optoelectronic semiconductor component according to claim 1, wherein the depression has a widened region between the active zone and the second semiconductor layer.

9. The optoelectronic semiconductor component according to claim 1, wherein the second contact structure comprises a connecting layer, and the connecting layer covers one or more surfaces of the semiconductor layer stack delimiting the at least one depression.

10. The optoelectronic semiconductor component according to claim 1, wherein the depression has a widened region between the active zone and the second semiconductor layer and a cavity exists in the widened region between the semiconductor layer stack and the second contact structure.

11. The optoelectronic semiconductor component according to claim 1, comprising an insulating layer, wherein the insulating layer is arranged between the semiconductor layer stack and a connecting layer of the second contact structure, wherein the connecting layer covers one or more surfaces of the semiconductor layer stack delimiting the at least one depression.

12. A method for producing at least one optoelectronic semiconductor component, the method comprising:
providing a semiconductor layer sequence for producing at least one semiconductor layer stack, the semiconductor layer sequence comprising:
a first semiconductor region,
a second semiconductor region,
an active zone which is arranged between the first and second semiconductor regions, wherein the second semiconductor region comprises a first semiconductor layer and a second semiconductor layer, and the second semiconductor layer is arranged on a side of the first semiconductor layer facing away from the active zone, and
a first main surface,
forming a first contact structure on the first main surface,
generating at least one depression which extends from the first main surface through the first semiconductor region and the active zone and ends at the second semiconductor layer,
forming a second contact structure which is arranged in some areas at the first main surface and in the at least one depression, wherein
the at least one depression is generated by a two-step etching process, and the semiconductor layer sequence is etched in a first etching step down into the first semiconductor layer and in a second etching step down to the second semiconductor layer.

13. The method according to claim 12, wherein the first etching step comprises a dry etching process.

14. The method according to claim 12, wherein the second etching step comprises a wet chemical etching process.

15. The method according to claim 12, wherein the first semiconductor layer is formed with a first compound semiconductor material and the second semiconductor layer is formed with a second compound semiconductor material, and the first compound semiconductor material has a higher aluminum content than the second compound semiconductor material.

16. The method according to claim 12, wherein the second etching step comprises a wet chemical etching process and for the wet chemical etching process an etching agent is used which has a higher etching rate for the first semiconductor layer having a higher aluminum content than for the second semiconductor layer having a lower aluminum content.

17. The method according to claim 12, wherein a widened region of the at least one depression is generated by means of the second etching step.

18. The method according to claim 12, wherein the active zone comprises a quantum well structure, and intermixing of the quantum well structure is performed in some areas of the active zone adjacent to the at least one depression.
